(19) United States
(12) Patent Application Publication
(10) Pub. No.: US 2011/0157858 A1
(43) Pub. Date: Jun. 30, 2011

(54) SYSTEM-IN-PACKAGE HAVING EMBEDDED CIRCUIT BOARDS

(75) Inventors: Ji-Hyun Jung, Seongnam-si (KR); Byung-Jik Kim, Seongnam-si (KR); Shi-Yun Cho, Anyang-si (KR); Ho-Seong Seo, Suwon-si (KR); Kyung-Wan Park, Suwon-si (KR); Yeun-Ho Choi, Seoul (KR); Yu-Su Kim, Yongin-si (KR); Seok-Myong Kang, Hwaseong-si (KR)

(73) Assignee: Samsung Electronics Co., Ltd., Suwon-si (KR)

(21) Appl. No.: 12/974,673

(22) Filed: Dec. 21, 2010

(30) Foreign Application Priority Data
Dec. 24, 2009 (KR) 10-2009-0131017

(51) Int. Cl. H05K 1/14

(52) U.S. Cl. 361/803

(57) ABSTRACT

Provided is a System-In-Package (SIP) having embedded circuit boards in which boards are electrically connected and a plurality of chips are embedded in a board in a stacked manner. The SIP includes a first board on a surface of which a first circuit is formed, a second board which is provided on a top surface of the first board in a stacked manner and includes a plurality of chips embedded therein in a stacked manner, and a third board which is provided on a top surface of the second board in a stacked manner and on a surface of which a second circuit is formed.

### PRIORITY

This application claims priority under 35 U.S.C. §119(a) to a Korean Patent Application filed in the Korean Intellectual Property Office on Dec. 24, 2009 and assigned Ser. No. 10-2009-131017, the entire disclosure of which is incorporated herein by reference.

### BACKGROUND OF THE INVENTION

1. Field of the Invention

The present invention relates generally to a system-in-package having embedded circuit boards, and more particularly, to a system-in-package having embedded circuit boards in which boards are electrically connected and a plurality of chips are embedded in a board in a stacked manner.

2. Description of the Related Art

As electric and electronic products have become more efficient, lightweight, and compact, increasing the density and integration of a package, which is a core device, has emerged as a big issue.

Since the package has been studied with the goal of decreasing size and thickness, various techniques for mounting a greater number of packages on a board having a limited size have been proposed and researched.

One way to provide a high-capacity semiconductor module may be increasing the capacity of a memory chip, that is, high integration of the memory chip, which may be achieved by integrating a large number of cells in a limited space of a semiconductor chip.

A System-In-Package (SIP) is structured such that at least two chips or packages are vertically stacked.

As shown in FIG. 1, a conventional SIP 1 includes a second Printed Circuit Board (PCB) 2 on a top surface of which a plurality of circuit patterns (not shown) are formed, a die 3 attached onto the second PCB 2, and a first PCB 2a including a plurality of chips 4 provided on the die 3 in a stacked manner.

The chips 4 and electrode terminals 2c of the first PCB 2a are electrically connected by bonding of wires 5, and the electrode terminal 2c of the first PCB 2a is also electrically connected with an electrode terminal 2b of the second PCB 2 by bonding to the wires 5.

A molding portion is formed on the second PCB 2 with a molding material to protect the entire top surface of the first PCB 2 and the second PCB 2a from an external environment.

However, as shown in FIG. 1, in the conventional SIP 1, the plurality of chips 4 are stacked on the first PCB 2a and connection is made by bonding of the wires 5, limiting thickness reduction because the thickness has to be sufficient for bonding of the wires 5. Moreover, noise may be generated between the wires 5 for connecting the stacked chips 4 with the first PCB 2a. Furthermore, to mount the first PCB 2a where the plurality of chips 4 are stacked on the second PCB 2, an Epoxy Molding Compound (EMC) 6a has to be first applied to the first PCB 2a, and after the first PCB 2a is mounted on the second PCB2, an EMC 6 has to be again applied, causing complexity in processing.

The plurality of chips 4 and the electrode terminals 2c of the first PCB 2a are connected by bonding of the wires 5, and, in case of a failure, it is difficult to identify a portion where the failure occurs and analyze a cause for the failure. Moreover, a separate test point pad has to be added for failure identification and performance test with respect to the first PCB 2a.

Accordingly, there is a need for an apparatus capable of reducing the thickness of an internal module of an SIP, reducing conventional use of several EMC applying processes to one time to reduce the manufacturing cost and time of a product, and providing a board terminal which allows for easy identification of a failure.

### SUMMARY OF THE INVENTION

Accordingly, an aspect of the present invention is to provide an SIP having embedded circuit boards, in which boards are electrically connected and a plurality of chips are embedded in a board in a stacked manner, thereby reducing the thickness of a product and achieving a slim, compact, and thin product.

Another aspect of the present invention is to provide an SIP having embedded circuit boards, in which boards are electrically connected and a board terminal is provided on a board to allow quality testing, thereby enabling an internal module test without a need for a separate test point, and thus facilitating failure identification in a product.

Moreover, another aspect of the present invention is to provide an SIP having embedded circuit boards, in which boards are electrically connected and a plurality of chips are embedded in a board in a stacked manner, thereby reducing multiple conventional EMC applying processes to a single EMC applying process and thus reducing manufacturing cost and time.

According to an aspect of the present invention, there is provided an SIP having embedded circuit boards. The SIP includes a first board on a surface of which a first circuit is formed, a second board which is provided on a top surface of the first board in a stacked manner and includes a plurality of chips embedded therein in a stacked manner, and a third board which is provided on a top surface of the second board in a stacked manner and on a surface of which a second circuit is formed.

### BRIEF DESCRIPTION OF THE DRAWINGS

The above and other features and advantages of an embodiment of the present invention will be more apparent from the following detailed description taken in conjunction with the accompanying drawings, in which:

FIG. 1 is a cross-sectional view of a conventional SIP;

FIG. 2 is a cross-sectional view of an SIP having embedded circuit boards according to an embodiment of the present invention; and

FIG. 3 is an enlarged cross-sectional view of the SIP having embedded circuit boards according to an embodiment of the present invention.

### DETAILED DESCRIPTION OF EMBODIMENTS OF THE PRESENT INVENTION

Hereinafter, an embodiment of the present invention will be described in detail with reference to the accompanying drawings. The embodiment disclosed in the specification and structures shown in the drawings are merely embodiments of the present invention and do not represent the technical spirit of the present invention. Therefore, it should be understood that various equivalents and variations capable of substituting for the embodiment may exist at the time of filing the application.

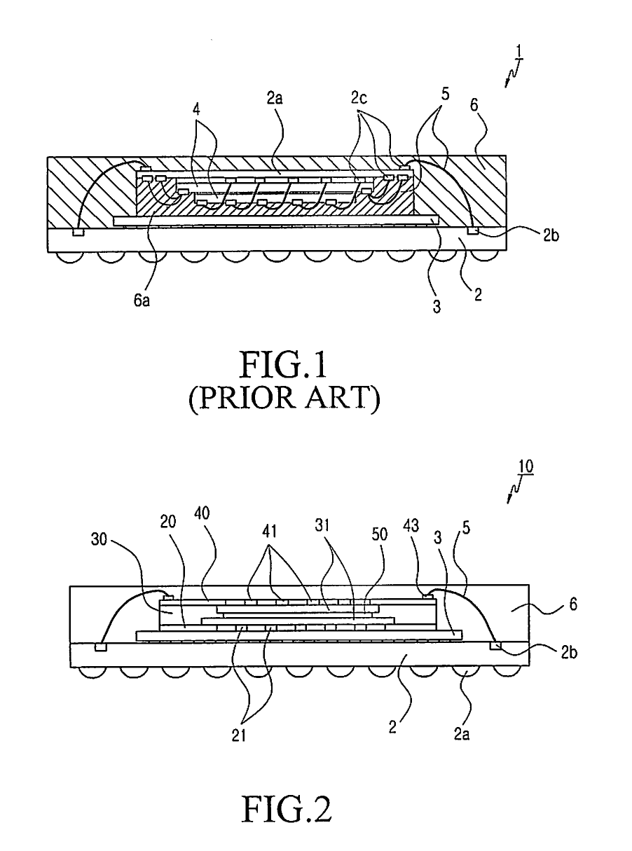

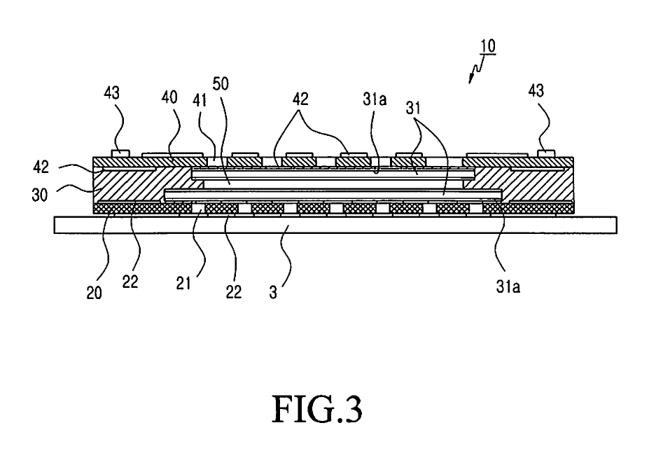

As shown in FIGS. 2 and 3, a System-In-Package (SIP) 10 having embedded circuit boards includes a PCB 2, a die 3, first and third boards 20 and 40, and a second board 30. The first board 20 is provided in a stacked manner on a top surface of the die 3, so that the first board 20 can be electrically connected with a plurality of chips 31 embedded in the second board 30. On a surface of the first board 20 is formed a first circuit 22 for electric connection with the die 3 and the plurality of chips 31. The second board 30 is provided in a stacked manner on a top surface of the first board 20 to embed the plurality of chips 31 therein in a stacked manner. The third board 40 is provided in a stacked manner on a top surface of the second board 30 for electric connection with the plurality of chips 31. On a surface of the third board 40 is formed a second circuit 42 to be electrically connected with the plurality of chips 31.

As shown in FIG. 3, the plurality of chips 31 are formed by stacking at least two Wafer Level Packages (WLPs).

As shown in FIGS. 2 and 3, a die attach film 50 is provided to attach the chips 31 to each other between the chips 31.

The first board 20 and the third board 40 may be copper (Cu) foil boards, but may also be made of other materials.

The second board 30 may be a Polypropylene Glycol (PPG) board, but may also be made of other materials.

On the third board 40 is provided a first board terminal 43 to be electrically connected with an electrode terminal 2b of the PCB 2 by bonding of wires 5.

On the first board 20 and the third board 40 are provided second board terminals 21 and 41, respectively, to identify a failure of a product and perform a test for internal connection checking.

The second board terminals 21 and 41 may include a bump part or a bump band.

On top and bottom surfaces of the chips 31 are provided electrodes 31 a for electric connection with the first circuit 22 on the first board 20 and the second circuit 42 on the third board 40.

Each of the chips 31 may include one of an integrated chip and a semiconductor chip.

As shown in FIGS. 2 and 3, the SIP 10 includes the first board 20 on a surface of which the first circuit 22 is formed, the second board 30, and the third board 40 on a surface of which the second circuit 42 is formed.

In this state, the die 3 is provided on the top surface of the PCB 2, and the first board 20 is provided on the die 3 in a stacked manner.

On the top surface of the first board 20 is provided the second board 30 in a stacked manner.

In the second board 30 are embedded the plurality of chips 31 in a stacked manner.

The first circuit 22 formed on the first board 20 is electrically connected with electrodes 31a of the chips 31 embedded in the second board 30.

The die attach film 50 is provided between the chips 31 of the second board 30 to attach the chips 31 to each other.

As shown in FIGS. 2 and 3, the third board 40 is provided on the top surface of the second board 30 in a stacked manner.

The second circuit 42 of the third board 40 is electrically connected with the electrodes 31a of the chips 31.

On the third board 40 is provided the first board terminal 43, which is electrically connected with the electrode terminal 2b of the PCB 2 by bonding of the wires 5.

In this state, the second board terminals 21 and 41 are provided on the first board 20 and the third board 40, respectively, to allow for identification of a failure of a product and perform a test for internal connection checking in the product, whereby the test for internal connection checking can be performed through the second board terminals 21 and 41 without a need to design a separate test point, and thus, failure identification can be easily performed.

As shown in FIGS. 2 and 3, the die 3 and the first board 20 are electrically connected by the first circuit 22, thereby preventing noise and signal interference from being generated during electric connection between the first board terminal 43 of the third board 40 and the electrode terminal 2b of the PCB 2 by bonding of the wires 5.

The first board 20 and the third board 40 are both Cu foil boards, and the second board 30 is a PPG board.

In this condition, as shown in FIGS. 2 and 3, the entire top surface of the PCB 2 is molded and thus sealed by an Epoxy Molding Compound (EMC) 6 to protect the first board 20, the second board 30, the third board 40, the chips 31, and the wires 5.

As such, by providing the SIP 10 having embedded circuit boards in which the plurality of chips 31 are embedded in a stacked manner, several EMC applying processes can be reduced to a single EMC applying process, thereby reducing the manufacturing cost and time of production, while achieving a compact and thin product.

The above-described SIP having embedded circuit boards according to the present invention is not limited by the foregoing embodiment and drawings, and it will be understood by those skilled in the art that various substitutions, modifications, and changes may be possible within the technical scope of the present invention.

What is claimed is:

1. A System-In-Package (SIP) having embedded circuit boards, the SIP comprising:
a first board on a surface of which a first circuit is formed;
a second board provided on a top surface of the first board in a stacked manner, the second board comprising a plurality of chips embedded therein in a stacked manner; and
a third board provided on a top surface of the second board in a stacked manner, the third board on a surface of which a second circuit is formed.

2. The SIP of claim 1, wherein the chips are formed by stacking at least two Wafer Level Packages (WLPs).

3. The SIP of claim 1, wherein a die attach film is provided between the chips.

4. The SIP of claim 1, wherein the first board and the third board are copper (Cu) foil boards and the second board is a Polypropylene Glycol (PPG) board.

5. The SIP of claim 1, wherein the third board comprises a first board terminal which is electrically connected with an electrode terminal of a Printed Circuit Board (PCB) included in the SIP by bonding of wires.

6. The SIP of claim 1, wherein on the first board and the third board are provided second board terminals, respectively, to perform a test for internal connection checking.

7. The SIP of claim 6, wherein the second board terminal comprises a bump part.

8. The SIP of claim 1, wherein on top and bottom surfaces of the chips are provided electrodes for electrical connection with the first circuit and the second circuit of the first board and the third board.
